(19) United States
(12) Patent Application Publication
(10) Pub. No.: US 2023/0215706 A1
(43) Pub. Date: Jul. 6, 2023

(54) LIFT PIN UNIT AND UNIT FOR SUPPORTING SUBSTRATE AND SUBSTRATE TREATING APPARATUS

(71) Applicant: SEMES CO., LTD., Cheonan-si (KR)

(72) Inventors: Yoon Seok CHOI, Suwon-si (KR); Hyun Woo JO, Hwaseong-si (KR); Sang Jeong LEE, Hwaseong-si (KR); Jong Won PARK, Hwaseong-si (KR); Hyoung Kyu SON, Seoul (KR)

(73) Assignee: SEMES CO., LTD., Cheonan-si (KR)

(21) Appl. No.: 18/148,078

(22) Filed: Dec. 29, 2022

(30) Foreign Application Priority Data
Dec. 31, 2021 (KR) 10-2021-0193642
Apr. 27, 2022 (KR) 10-2022-0052161

(51) Int. Cl. H01J 37/32; H01L 21/687; H01L 21/683

(52) U.S. Cl. CPC H01J 37/32715; H01J 37/32642; H01L 21/68742; H01L 21/6833; H01J 2237/20235; H01J 2237/2007; H01J 2237/002; H01J 2237/334

(57) ABSTRACT

The inventive concept provides a substrate support unit. The substrate support unit includes a susceptor supporting the substrate and having a pinhole formed vertically; and a lift pin unit configured to load and unload the substrate on the susceptor, and wherein the lift pin unit includes: a lift pin vertically movable along the pinhole; a support vertically movable by a driving unit; a pin holder connecting the support and the lift pin, and wherein the lift pin is pivotably connected to the pin holder and the pin holder is laterally movable with respect to the support.

### CROSS-REFERENCE TO RELATED APPLICATIONS

This application claims priority under 35 U.S.C. § 119 to Korean Patent Application No. 10-2021-0193642 filed on Dec. 31, 2021 and Korean Patent Application No. 10-2022-0052161 filed on Apr. 27, 2022, in the Korean Intellectual Property Office, the disclosures of which are incorporated by reference herein in their entireties.

### BACKGROUND

Embodiments of the inventive concept described herein relate to a lift pin unit for mounting a substrate on a top portion of a substrate support and a substrate support unit including the same.

In general, a plasma refers to an ionized gas state including ions, radicals, electrons, etc. The plasma may be generated under very high temperatures, strong electric fields, or RF electromagnetic fields. A semiconductor device manufacturing process may include an etching process of removing a thin film formed on a substrate such as a wafer using the plasma. The etching process is performed by colliding or reacting ions and/or radicals of the plasma with the thin film on the substrate.

In treating the substrate using the plasma, a straightness of the ions and/or the radicals included in the plasma is important. The straightness of the ions and/or radicals contained in the plasma acts as an important factor in determining an etching selectivity. An electrostatic chuck supporting the substrate may be cooled down to a low temperature in order to increase the straightness of the ions and/or the radicals.

In a cryogenic plasma apparatus which performs a plasma treatment in an cryogenic environment of −30 degrees Celsius or below, a substrate supporting unit may become cryogenic by refrigerants circulating within and thereby shrunken, and a huge stress is put on a fastening and fixing part of the lift pin, causing a serious issue in a facility operation such as a breakage of the fastening and fixing part.

### SUMMARY

Embodiments of the inventive concept provide a lift pin unit and a substrate support unit and substrate treating apparatus including the same, for smoothly dealing with a heat modification (shrinking) of the substrate support unit.

The technical objectives of the inventive concept are not limited to the above-mentioned ones, and the other unmentioned technical objects will become apparent to those skilled in the art from the following description.

The inventive concept provides a substrate support unit for supporting a substrate. The substrate support unit includes a susceptor supporting the substrate and having a pinhole formed vertically; and a lift pin unit configured to load and unload the substrate on the susceptor, and wherein the lift pin unit includes: a lift pin vertically movable along the pinhole; a support vertically movable by a driving unit; a pin holder connecting the support and the lift pin, and wherein the lift pin is pivotably connected to the pin holder and the pin holder is laterally movable with respect to the support.

In an embodiment, the lift pin includes a joint ball, and the pin holder includes a ball socket into which the joint ball is inserted for pivoting of the join ball.

In an embodiment, the lift pin unit further includes a first elastomer for providing a restoring force to restore the lift pin to an original coaxial position with the pin holder from a non-coaxial position with the pin holder caused by pivoting of the joint ball.

In an embodiment, the first elastomer includes a pin-shaped elastomer having one end inserted into a first insertion groove of the join ball and the other opposite end of the first elastomer inserted into a second insertion groove of the ball socket.

In an embodiment, the first insertion groove and the second insertion groove are vertically aligned.

In an embodiment, the lift pin unit further includes a second elastomer for proving a restoring force to restore the pin holder to an original position with respect to the support from laterally moved position.

In an embodiment, the second elastomer includes a pin-shaped elastomer having one end inserted into a third insertion groove formed at a bottom of the pin holder and the other opposite end of the second elastomer inserted into a fourth insertion groove formed a top of the support.

In an embodiment, the third insertion groove and the fourth insertion groove are vertically aligned.

The inventive concept provides a lift pin unit for loading and unloading a substrate. The lift pin unit includes a lift pin; a support vertically movable by a driving unit; and a pin holder connecting the support and the lift pin, and wherein the lift pin is pivotably connected to the pin holder, and wherein the lift pin includes a joint ball, and the pin holder includes a ball socket into which the joint ball is inserted for pivoting of the joint ball.

In an embodiment, the lift pin unit further includes a first elastomer for providing a restoring force to restore the lift pin to an original coaxial position with the pin holder from a non-coaxial position with the pin holder caused by pivoting of the joint ball.

In an embodiment, the first elastomer includes a pin-shaped elastomer having one end inserted into a first insertion groove of the joint ball and the other opposite end inserted into a second insertion groove of the ball socket.

In an embodiment, the first insertion groove and the second insertion groove are vertically aligned.

In an embodiment, the pin holder is laterally movably connected to the support, and wherein the lift pin unit further includes a second elastomer for providing a restoring force to restore the pin holder to an original position with the support from laterally moved position.

In an embodiment, the second elastomer includes a pin-shaped elastomer having one end inserted into a third insertion groove formed at bottom of the pin holder and the other opposite end inserted into a fourth insertion groove formed a top the support.

In an embodiment, the third insertion groove and the fourth insertion groove are vertically aligned.

In an embodiment, the pin holder includes a top holder connected to the lift pin and a bottom holder connected to the support, and wherein the top holder and the bottom holder are threadedly connected.

The inventive concept provides a substrate treating apparatus. The substrate treating apparatus includes a process chamber defining a treating space; a gas supply unit configured to supply a process gas into the process chamber; a plasma generation unit configured to generate a plasma from the process gas introduced into the process chamber; and a substrate support unit provided at the treating space and configured to support a substrate, and wherein the substrate support unit includes: a dielectric plate having an electrostatic electrode therein electrostatically adsorbing the substrate; an electrode plate provided below the dielectric plate and having a fluid channel; a focus ring in a ring shape provided at a periphery of the dielectric plate; an insulator plate provided below the electrode plate; a base plate provided below the insulator plate and grounded; and a lift pin unit provided in an inner space of the base plate, and wherein lift pin unit includes: a lift pin inserted into a pin hole penetrating the dielectric plate, the electrode plate, and the insulator plate; a support vertically movable by a driving unit; and a pin holder connecting the support unit and the lift pin, and wherein the lift pin is pivotably connected to the pin holder pivotable on a central axis of the pinhole, and the pin holder is vertically movably connected to the support unit.

In an embodiment, the lift pin includes a joint ball, and the pin holder includes a ball socket into which the joint ball is inserted for pivoting of the joint ball, and the lift pin unit further includes a first elastomer for providing a restoring force to restore the lift pin to an original position coaxial with the central axis of the pin hole from a pivotally moved position.

In an embodiment, the lift pin unit further includes a second elastomer for providing a restoring force to restore the pin holder to an original position coaxial with the central axis of the pin hole from a laterally moved position, and wherein the second elastomer includes a pin-shaped elastomer having one end inserted into an insertion groove formed at a bottom of the pin holder and the other opposite end inserted into an insertion grooved formed a top of the support.

In an embodiment, the process chamber treats the substrate using a cryogenic plasma.

According to an embodiment of the inventive concept, a damage of a lift pin may be prevented by smoothly dealing with a heat modification (shrinking) of a substrate support unit.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 schematically illustrates a substrate treating apparatus according to an embodiment of the inventive concept.

FIG. 2 is a cross-sectional view illustrating a process module illustrated in FIG. 1.

FIG. 3 illustrates a pinhole.

FIG. 4 is an enlarged view of a main part shown in FIG. 2.

FIG. 5 is a cross-sectional view illustrating a coupling state between a lift pin and a pin holder in FIG. 4.

FIG. 6 is an exploded perspective view illustrating the lift pin and the pin holder of FIG. 5.

FIG. 7A and FIG. 7B illustrate that the lift pin is originally positioned in a vertical central axis C by a first elastic modification member and a second elastic modification member.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described in detail with reference to the accompanying drawings.

In an embodiment of the inventive concept, a substrate treating apparatus for etching a substrate using a plasma will be described. However, the inventive concept is not limited thereto, and may be applied to various types of apparatuses that perform a process by supplying the plasma into a chamber.

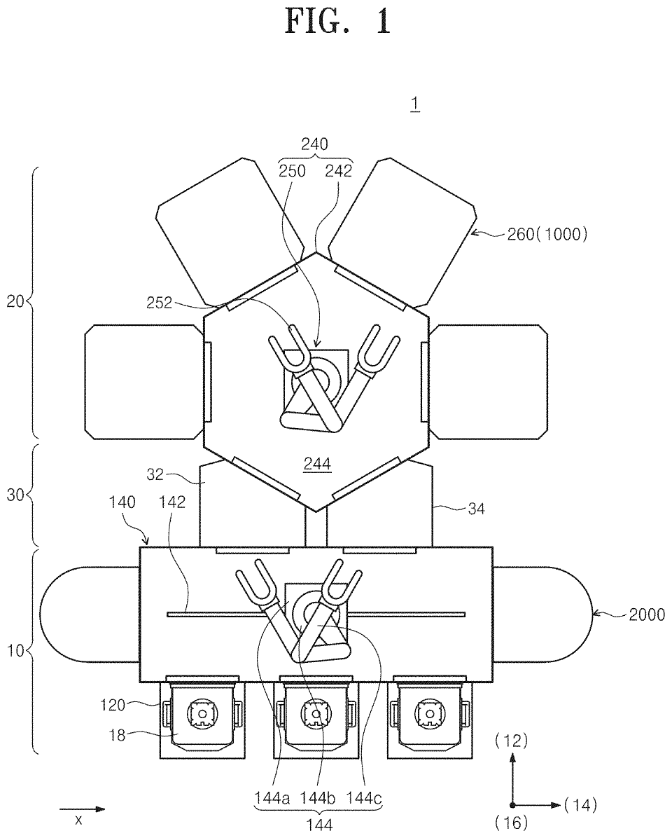

Referring to FIG. 1, the substrate treating apparatus 1 includes an index module 10, a loading module 30, and a process module 20.

The index module 10 may include a load port 120, a transfer frame 140, and a buffer unit 2000, and the load port 120, the transfer frame 140, and the process module 20 may be sequentially arranged in a row.

Hereinafter, a direction in which the load port 120, the transfer frame 140, the loading module 30, and the process module 20 are arranged is referred to as a first direction 12, a direction perpendicular to the first direction 12 when seen from above is referred to as a second direction 14, and a direction perpendicular to a plane including the first direction 12 and the second direction 14 is referred to as a third direction 16.

A carrier 18 in which a plurality of substrates W are stored is mounted on the load port 120. The load port 120 are provided in plural and the plurality of load ports 120 are arranged in a line along the second direction 14. A slot (not shown) provided to support an edge of the substrate is formed in the carrier 18. A plurality of slots are provided in the third direction 16, and the substrates are positioned in the carrier to be stacked while being spaced apart from each other along the third direction 16. A front opening unified pod (FOUP) may be used as the carrier 18.

The transfer frame 140 transfers the substrate W between the carrier 18 mounted on the load port 120, the buffer unit 2000, and the loading module 30. An index rail 142 and an index robot 144 are provided in the transfer frame 140. A lengthwise direction of the index rail 142 is provided parallel to the second direction 14. The index robot 144 is installed on the index rail 142 and moves linearly in the second direction 14 along the index rail 142. The index robot 144 has a base 144a, a body 144b, and an index arm 144c. The base 144a is installed to be movable along the index rail 142. The body 144b is coupled to the base 144a. The body 144b is provided to be movable along the third direction 16 on the base 144a.

In addition, the body 144b is provided to be rotatable on the base 144a. The index arm 144c is coupled to the body 144b and is provided to be forwardly and backwardly movable with respect to the body 144b. A plurality of index arms 144c are provided to be individually driven. The index arms 144c are disposed to be stacked while being spaced apart from each other in the third direction 16. Some of the index arms 144c may be used to transfer the substrate W from the process module 20 to the carrier 18, and the others may be used to transfer the substrate W from the carrier 18 to the process module 20. This may prevent particles generated from the substrate W to be treated from being attached to the substrate W which has been treated during taking in and taking out the substrate W by the index robot 144.

The buffer unit 2000 temporarily stores the substrate W. The buffer unit 2000 performs a process of removing process by-products remaining on the substrate W. The buffer unit 2000 performs a post-treatment process of post-treating the substrate W which has been treated at the process module 20. The post-treatment process may be a process of purging a purge gas on the substrate W. A plurality of buffer units 2000 are provided. Buffer units 2000 are positioned opposite sides of the transfer frame 140 along the second direction 14. Alternatively, one or more of the buffer unit 2000 may be provided at one side of the transfer frame 140. The loading module 30 is disposed between the transfer frame 140 and the transfer unit 240. The loading module 30 replaces an atmospheric pressure atmosphere of the index module 10 with a vacuum atmosphere of the process module 20 with respect to the substrate W taken into the process module 20 or replaces the vacuum atmosphere of the process module 20 with the atmospheric pressure atmosphere of the index module 10 with respect to the substrate taken back to the index module 10. The loading module 30 provides a space in which the substrate W stays before being transferred between the transfer unit 240 and the transfer frame 140. The loading module 30 includes a load lock chamber 32 and an unload lock chamber 34.

In the load lock chamber 32, the substrate W transferred from the index module 10 to the process module 20 temporarily stays. The load lock chamber 32 maintains an atmospheric pressure atmosphere in the standby state and is blocked from the process module 20 while maintaining an open state to the index module 10. When the substrate W is taken into the load lock chamber 32, the inner space of the load lock chamber 32 is sealed with respect to each of the index module 10 and the process module 20. Afterwards, the inner space of the load lock chamber 32 is replaced from an atmospheric pressure atmosphere to a vacuum atmosphere, and is opened to the process module 20 while being blocked from the index module 10.

In the unload lock chamber 34, the substrate W transferred from the process module 20 to the index module 10 temporarily stays. The unloaded lock chamber 34 maintains a vacuum atmosphere in a standby state and is blocked from the index module 10 while maintaining an open state with respect to the process module 20. If the substrate W is taken into the unload lock chamber 34, the inner space of the unload lock chamber 34 is sealed with respect to each of the index module 10 and the process module 20. Afterwards, an inner space of the unloaded lock chamber 34 is replaced from a vacuum atmosphere to an atmospheric pressure atmosphere, and is opened to the index module 10 while being blocked from the process module 20.

The process module 20 may include a transfer unit 240 and a plurality of process chambers.

The transfer unit 240 transfers the substrate W between the load lock chamber 32, the unload lock chamber 34, and the plurality of process chambers 260. The transfer unit 240 includes a transfer chamber 242 and a transfer robot 250. The transfer chamber 242 may have a hexagonal shape. In another embodiment, the transfer chamber 242 may have a rectangular or pentagonal shape. The load lock chamber 32, the unload lock chamber 34, and the plurality of process chambers 260 are positioned around the transfer chamber 242. A transfer space 244 for transferring the substrate W is provided inside of the transfer chamber 242.

The transfer robot 250 transfers the substrate W in the transfer space 244. The transfer robot 250 may be positioned in a central part of the transfer chamber 240. The transfer robot 250 may have a plurality of hands 252 which may move in a horizontal and vertical direction and may move forwardly, backwardly, or rotate on a horizontal plane. Each hand 252 may be independently driven, and the substrate W may be mounted on the hand 252 in a horizontal state.

Hereinafter, a plasma treating apparatus 1000 provided in the process chamber 260 will be described. The plasma treating apparatus 1000 will be described as an apparatus for etching the substrate W. However, the plasma treating apparatus 1000 of the inventive concept is not limited to the etching treating apparatus, and may be variously applied.

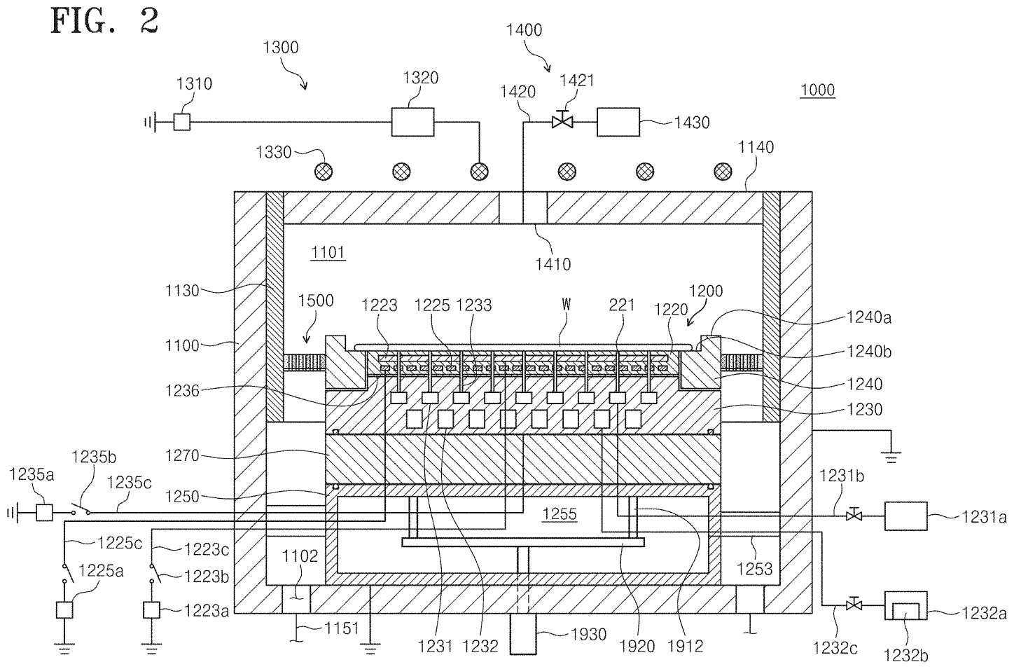

FIG. 2 is a cross-sectional view illustrating a process module according to an embodiment of the inventive concept.

Referring to FIG. 2, the plasma treating apparatus 1000 may include a process chamber 1100, a substrate support unit 1200, a gas supply unit 1300, a plasma source 1400, an exhaust baffle 1500, and an image acquisition member 700.

Referring to FIG. 2, the plasma treating apparatus 1000 treats a wafer W using a plasma. As an embodiment of a substrate, a semiconductor wafer (hereinafter, simply referred to as a “wafer W”) is provided.

The plasma treating apparatus 1000 may include a process chamber 1100, a substrate support unit 1200, a plasma generation unit 1300, a gas supply unit 1400, a baffle unit 1500, and a controller (not shown).

The process chamber 1100 provides a treating space 1101 in which a substrate treating process is performed. The treating space 1101 may be maintained at a process pressure lower than an atmospheric pressure, and may be provided as a sealed space. The process chamber 1100 may be made of a metal material. In an embodiment, the process chamber 1100 may be made of an aluminum material. A surface of the process chamber 1100 may be anodized. The process chamber 1100 may be electrically grounded. An exhaust hole 1102 may be formed on a bottom surface of the process chamber 1100. The exhaust hole 1102 may be connected to an exhaust line 1151. The reaction by-products generated during the process and a gas remaining in the inner space of the chamber may be discharged to an outside through the exhaust line 1151. The inside of the process chamber 1100 may be depressurized to a predetermined pressure by an exhaust process.

According to an embodiment, a liner 1130 may be provided inside the process chamber 1100. The liner 1130 may have a cylindrical shape with an open top side and a bottom side. The liner 1130 may be provided to be in contact with an inner sidewall of the chamber 1100. The liner 1130 may protect the inner sidewall of the chamber 1100, preventing the inner sidewall of the chamber 1100 from being damaged by an arc discharge. In addition, it is possible to prevent byproducts generated during the substrate treatment process from being deposited on the inner sidewall of the chamber 1100. The liner 1130 may include an yttria (Y₂O₃) material. The liner 1130 exposed inside the treating space may react with a first cleaning gas introduced into the treating space.

A window 1140 is provided on a top of the process chamber 1100. The window 1140 is provided in a plate shape. The window 1140 covers the process chamber 1100 to seal the treating space 1101. The window 1140 may include a dielectric substance.

A substrate support unit 1200 is provided inside the process chamber 1100. In an embodiment, the substrate support unit 1200 may be positioned inside the chamber 1100 at a predetermined distance from a bottom surface of the chamber 1100. The substrate support unit 1200 may support the wafer W. The substrate support unit 1200 may include an electrostatic chuck ESC including an electrostatic electrode 1223 which adsorbs the wafer W using an electrostatic force. In some embodiments, the substrate support unit 1200 may support the wafer W in various ways, such as a mechanical clamping. Hereinafter, the substrate support unit 1200 including the electrostatic chuck ESC will be described as an example.

The substrate support unit 1200 may include a susceptor, a base plate 1250, and a lift pin unit 1900. The susceptor may be provided in the form of a module including a dielectric plate 1220, an electrode plate 1230, and an insulator plate 1270.

The dielectric plate 1220 and the electrode plate 1230 may form an electrostatic chuck ESC. The dielectric plate 1220 may support the wafer W. The dielectric plate 1220 may be surrounded by a focus ring 1240. The dielectric plate 1220 may be positioned at a top end of the electrode plate 1230. The dielectric plate 1220 may be provided as a dielectric substrate having a disk shape. A wafer W may be placed on a top surface of the dielectric plate 1220. The top surface of the dielectric plate 1220 may have a smaller radius than the wafer W. Therefore, an edge region of the wafer W may be positioned outside the dielectric plate 1220. An edge of the wafer W may be placed on a top surface of the focus ring 1240.

The dielectric plate 1220 may include an electrostatic electrode 1223, a heater 1225, and a first supply fluid channel 1221 therein. The first supply fluid channel 1221 may be formed to extend from a top surface to a bottom surface of the dielectric plate 1220. A plurality of first supply fluid channels 1221 are formed to be spaced apart from each other, and may be provided as a path through which a heat transfer medium is supplied to a bottom surface of the wafer W.

The electrostatic electrode 1223 may be electrically connected to a first power source 1223a. The first power source 1223a may include a DC power. A switch 1223b may be installed between the electrostatic electrode 1223 and the first power source 1223a. The electrostatic electrode 1223 may be electrically connected/disconnected from the first power source 1223a by the on/off operation of the switch 1223b. If the switch 1223b is turned on, a DC current may be applied to the electrostatic electrode 1223. An electrostatic force generates between the electrostatic electrode 1223 and the wafer W by a current applied to the electrostatic electrode 1223, and the wafer W may be adsorbed to the dielectric plate 1220 by the electrostatic force.

The heater 1225 may be positioned below the electrostatic electrode 1223. The heater 1225 may be electrically connected to a second power source 1225a. The heater may be configured to undergo Joule heating (which is also known as ohmic/resistive heating) upon the application of an electric current thereto by the second power source. For example, the heater may be configured to produce heat when an electric current passes therethrough. The generated heat may be transferred to the wafer W through the dielectric plate 1220. The wafer W may be maintained at a predetermined temperature by the heat generated by the heater 1225. The heater 1225 may include a coil having a spiral shape.

The electrode plate 1230 may be positioned below the dielectric plate 1220. A bottom surface of the dielectric plate 1220 and a top surface of the electrode plate 1230 may be adhered to each other by an adhesive 1236. The electrode plate 1230 may be made of an aluminum material. The top surface of the electrode plate 1230 may be stepped so that a central region is positioned higher than an edge region. The top center part of the electrode plate 1230 has an area corresponding to the bottom surface of the dielectric plate 1220, and may be adhered to the bottom surface of the dielectric plate 1220. The electrode plate 1230 may have a first circulation fluid channel 1231, a second circulation fluid channel 1232, and a second supply fluid channel 1233.

The first circulation fluid channel 1231 may be provided as a passage through which a heat transfer medium circulates. The first circulation fluid channel 1231 may be formed in a spiral shape within the electrode plate 1230. Also, the first circulation fluid channel 1231 may be disposed such that ring-shaped fluid channels having different radii have the same center. Each of the first circulation fluid channels 1231 may communicate with each other. The first circulation fluid channels 1231 may be formed at the same height.

The second circulation fluid channel 1232 may be provided as a passage through which a refrigerant circulates. The second circulation fluid channel 1232 may be formed in a spiral shape inside the electrode plate 1230. Also, the second circulation fluid channel 1232 may be disposed such that ring-shaped fluid channels having different radii have the same center. Each of the second circulation fluid channels 1232 may communicate with each other. The second circulation fluid channel 1232 may have a cross-sectional area greater than that of the first circulation fluid channel 1231. The second circulation fluid channels 1232 may be formed at the same height. The second circulation fluid channel 1232 may be formed under the first circulation fluid channel 1231.

The second supply fluid channel 1233 may upwardly extend from the first circulation fluid channel 1231 and may be positioned over a top surface of the electrode plate 1230. The second supply fluid channel 1243 may be provided in a number corresponding to the first supply fluid channel 1221, and may connect the first circulation fluid channel 1231 and the first supply fluid channel 1221.

The first circulation fluid channel 1231 may be connected to a heat transfer medium storage unit 1231a via a heat transfer medium supply line 1231b. A heat transfer medium may be stored in the heat transfer medium storage unit 1231a. The heat transfer medium may include an inert gas. According to an embodiment, the heat transfer medium may include a helium (He) gas. The helium gas may be supplied to the first circulation fluid channel 1231 through the supply line 1231b, and may be supplied to a bottom surface of the wafer W through the second supply fluid channel 1233 and the first supply fluid channel 1221. The helium gas may serve as a medium in which the heat transferred from the plasma to the wafer W is transferred to the dielectric plate 1220.

The second circulation fluid channel 1232 may be connected to a refrigerant storage unit 1232a via a refrigerant supply line 1232c. A refrigerant may be stored in the refrigerant storage unit 1232a. A cooler 1232b may be provided in the refrigerant storage unit 1232a. The cooler 1232b may cool the refrigerant to a predetermined temperature. In an embodiment, the cooler 1232b may be installed on the refrigerant supply line 1232c. The refrigerant supplied to the second circulation fluid channel 1232 through the refrigerant supply line 1232c may circulate along the second circulation fluid channel 1232 to cool the electrode plate 1230. While the electrode plate 1230 is cooled, the dielectric plate 1220 and the wafer W may be cooled together to maintain the wafer W at a predetermined temperature. In an embodiment, the refrigerant may be cooled to 0° C. or lower (low temperature) and supplied. In a preferred embodiment, the refrigerant may be cooled to −30° C. or lower (extremely low temperature). In an embodiment, the refrigerant cools the electrode plate 230 to an extremely low temperature in a range of −30° C. to −100° C., preferably in a range of −30° C. to −60° C.

The electrode plate 1230 may include a metal plate. According to an embodiment, the entire electrode plate 1230 may be provided as a metal plate. The electrode plate 1230 may be electrically connected to a third power source 1235a. The third power source 1235a may be provided as a high frequency power source which generates a high frequency power. The high-frequency power source may include an RF power. The electrode plate 1230 may receive the high frequency power from the third power source 1235a. Accordingly, the electrode plate 1230 may function as an electrode, that is, a bottom electrode.

The focus ring 1240 may be disposed in an edge region of the dielectric plate 1220. The focus ring 1240 has a ring shape and may be disposed along a circumference of the dielectric plate 1220. The top surface of the focus ring 1240 may be stepped so that an outer portion 1240a is higher than an inner portion 1240b. An inner portion 1240b of the top surface of the focus ring 1240 may be positioned at the same height as the top surface of the dielectric plate 1220. The inner portion 1240b of the top surface of the focus ring 1240 may support an edge region of the wafer W positioned outside the dielectric plate 1220. The outer portion 1240a of the focus ring 1240 may be provided to surround the edge region of the wafer W. The focus ring 1240 may control an electromagnetic field so that a density of the plasma is uniformly distributed in the entire region of the wafer W. Accordingly, the plasma is uniformly formed over an entire region of the wafer W, so that each region of the wafer W may be uniformly etched.

The base plate 1250 may be positioned at a bottom end of the substrate support unit 1200. A space 1255 may be formed within the base plate 1250. The space 1255 formed by the base plate 1250 may communicate with the outside of the space 1255. An outer radius of the base plate 1250 may be provided to have the same length as an outer radius of the electrode plate 1230.

An insulator plate 1270 may be positioned between the dielectric plate 1220 and the base plate 1250. The insulator plate 1270 may cover a top surface of the base plate 1250. The insulator plate 1270 may be provided in a cross-sectional area corresponding to the electrode plate 1230. The insulator plate 1270 may include an insulator. The insulator plate 1270 may serve to increase an electrical distance between the electrode plate 1230 and the base plate 1250.

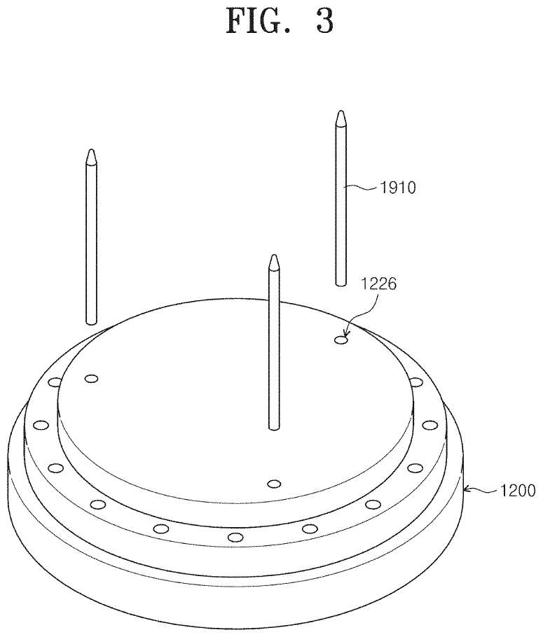

FIG. 3 illustrates a pinhole.

As shown in FIG. 3, the pin hole 1226 is formed in the dielectric plate 1220. The pin hole 1226 is formed on the top surface of the dielectric plate 1220. Also the pin hole 1236 may vertically penetrate the thickness of the dielectric plate 1220. Although not shown, the pin hole 1226 is provided to communicate with bottom lower space 1225 of the base plate passing the electrode plate 1230 and the insulator plate 1270 sequentially from the top surface of the dielectric plate 1220.

A plurality of pin holes 1226 may be formed. The plurality of pin holes 1226 may be disposed in the circumferential direction of the dielectric plate 1220. For example, three pin holes 1226 may be spaced with the same distance along the circumferential direction of the dielectric plate 1220. In addition, any number of pin holes 1226 can be formed, such as four pin holes 1226 may be arranged with the same distance along the circumferential direction of the dielectric plate 1220.

A lift pin unit 1900 may be positioned in the inner space 1255 of the base plate 1250 to move the transferred wafer W from the outer transfer member to the dielectric plate 1220. The lift pin unit 1900 may be positioned to be spaced apart from the base plate 1250 by a predetermined interval. The base plate 1250 may be made of a metal material. An air may be provided in the inner space 1255 of the base plate 1250. Since the air has a dielectric constant lower than that of the insulator, it may serve to reduce an electromagnetic field inside the substrate support unit 1200.

The base plate 1250 may have a connection member 1253. The connection member 1253 may connect an outer surface of the base plate 1250 with an inner sidewall of the chamber 1100. A plurality of connection members 1253 may be provided on the outer surface of the base plate 1250 at regular intervals. The connection member 1253 may support the substrate support unit 1200 inside the chamber 1100. In addition, the connection member 1253 may be connected to the inner wall of the chamber 1100 so that the base plate 1250 may be electrically grounded. The first power line 122c connected to the first power source 1223a, the second power line 1225c connected to the second power source 1225a, the third power line 1235c connected to the third power source 1235a, the heat transfer medium supply line 1231b connected to the heat transfer medium storage unit 1231a, and the refrigerant supply line 1232c connected to the refrigerant storage unit 1232a may extend inside of the base plate 1250 through the inner space 1255 of the connection member 1253.

A plasma generation unit 1300 may excite the process gas in the chamber 1100 into a plasma state. The plasma generation unit 1300 may use an inductively coupled plasma type plasma source. If an ICP type plasma source is used, the antenna 1330 provided on the top part of the chamber 1100 and electrode plate 1230 provided inside the chamber may function as two opposite electrodes. The antenna 1330 and the electrode plate 1230 may be vertically disposed in parallel with each other with the treating space 1101 interposed therebetween. Not only the electrode plate 1230 but also the antenna 330 can receive an energy for generating the plasma by receiving RF signals from the RF power source 1310. An electric field is formed in the space between both electrodes, and the process gas supplied to the space may be excited in the plasma state. A substrate treatment process is performed using this plasma. An RF signal applied to the antenna 1330 and the electrode plate 1230 may be controlled by a controller (not shown). According to an embodiment of the inventive concept, a waveguide 1320 may be disposed on the antenna 1330, and the waveguide 1320 transmits an RF signal provided from the RF power source 1310 to the antenna 1330. The waveguide 1320 may have a conductor that may be introduced into the waveguide. The plasma generated by the plasma generating unit 1300 treats the wafer W cooled to an extremely low temperature (−30° C. or lower). As described above, a plasma treatment of the wafer W in an extremely low temperature environment is referred to as an extremely low temperature plasma process.

The gas supply unit 1400 may supply a process gas into the chamber 1100. The gas supply unit 1400 may include a gas supply nozzle 1410, a gas supply line 1420, and a gas storage unit 1430.

The gas supply nozzle 1410 may be installed at a central portion of the window 1140, which is a top surface of the chamber 1100. An injection hole may be formed on a bottom surface of the gas supply nozzle 1410. The injection hole may supply the process gas into the chamber 1100. The gas supply line 1420 may connect the gas supply nozzle 1410 and the gas storage unit 1430. The gas supply line 1420 may supply the process gas stored in the gas storage unit 1430 to the gas supply nozzle 1410. A valve 1421 may be installed in the gas supply line 1420. The valve 1421 may open and close the gas supply line 1420, and may adjust a flow rate of the process gas supplied through the gas supply line 1420.

The process gas supplied by the gas supply unit 1400 may be at least one of a CF₄ (methane), an H₂ (hydrogen bromide), an NF₃ (nitrogen trifluoride), a CH₂F₂ (difluoromethane), an O₂ (oxygen), an F₂ (fluorine), an HF (hydrogen fluoride), or a combination thereof. Meanwhile, a proposed process gas may be selected differently as necessary despite an embodiment. The process gas according to an embodiment of the inventive concept is excited in a plasma state to etch the substrate.

The baffle unit 1500 may be positioned between the inner sidewall of the chamber 1100 and the substrate support unit 1200. The baffle 1510 may be provided in a ring shape. A plurality of through holes 1511 may be formed in the baffle 1510. The process gas provided in the process chamber 1100 may pass through the through holes 1511 of the baffle 1510, and may be exhausted to the exhaust hole 1102. A flow of process gas may be controlled according to a shape of the baffle 1510 and a shape of the through holes 1511.

A controller (not shown) may control an overall operation of the substrate treating apparatus 1000. The controller (not shown) may include a central processing unit (CPU), a read only memory (ROM), and a random access memory (RAM). The CPU executes a desired processing such as an etching treatment to be described below according to various recipes stored in the storage area thereof. The recipe contains a process time, a process pressure, a high-frequency power or voltage, various gas flow rates, a temperature within the chamber (a temperature of the top electrode, a sidewall temperature of the chamber, a electrostatic chuck temperature, etc.), and a temperature of the cooler 1232b. Meanwhile, a recipe indicating these programs or treating conditions may be stored in a hard disk or a semiconductor memory. In addition, the recipe may be set at a predetermined location in the storage area while being stored in a readable storage medium by a portable computer such as a CD-ROM and a DVD.

Meanwhile, the lift pin unit 900 loads the substrate W on the dielectric plate 1220 or unloads the substrate W from the dielectric plate 1220 through a lifting and lowering movement.

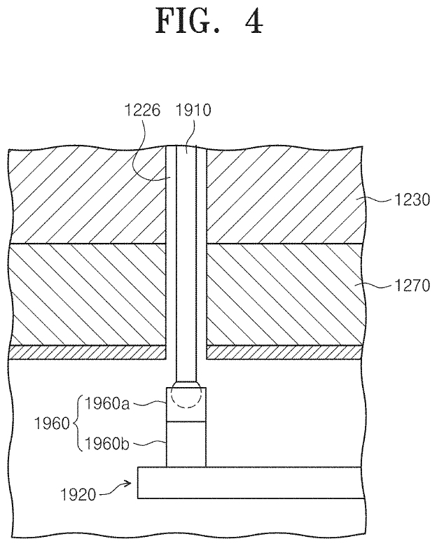

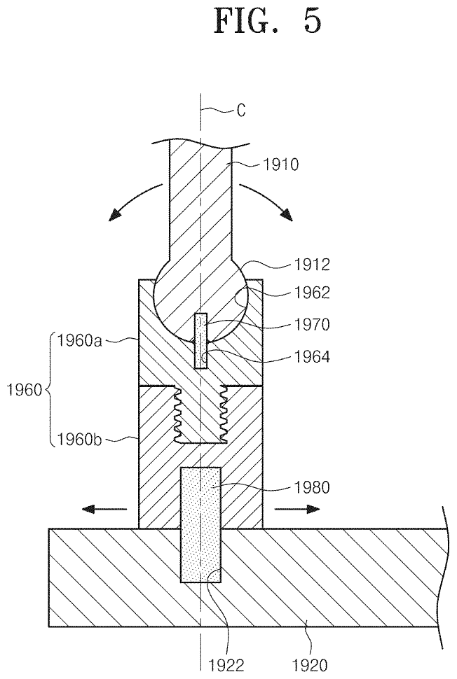

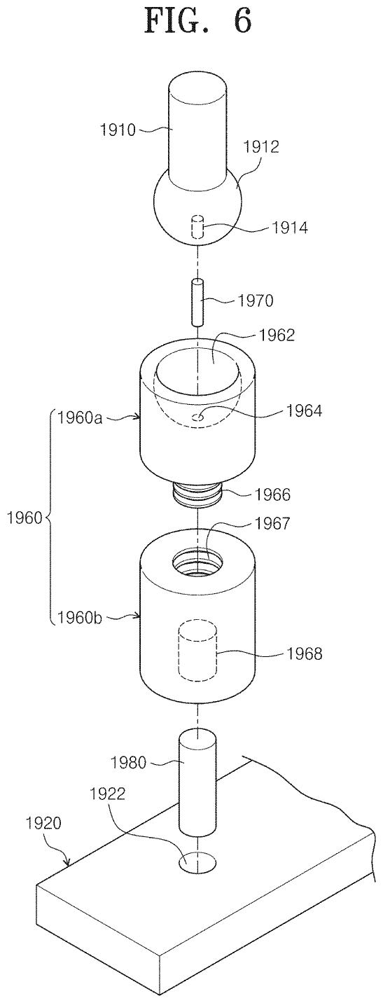

FIG. 4 is an enlarged view of the main part shown in FIG. 2, FIG. 5 is a cross-sectional view showing a coupling state between the lift pin and the pin holder in FIG. 4, and FIG. 6 is an exploded perspective view for explaining the lift pin and the pin holder of FIG. 5.

Referring to FIG. 2 to FIG. 6, the lift pin unit 1900 may include a lift pin 1910, a pin holder 1960, a support unit 1920, a driving unit 1930, a first elastic member 1970, and a second elastic member 1980.

A plurality of lift pins 1910 are provided and are received in respective pin hole 1226. Here, a diameter of the lift pin 1910 is smaller than a diameter of the pin hole 1226. Specifically, the diameter of the lift pin 1910 may be provided with a minimum diameter that does not contact an inner sidewall of the pin hole 1226 when the lift pin 1910 is received in the pin hole 1226 to have the same central axis with the pin hole 1226.

Meanwhile, the lift pin 1910 has a joint ball 1912 at a lower end. The lift pins 1910 move vertically along the pin holes 1226 and load/unload the substrate W. In an embodiment, the lift pin 1910 rises to support the substrate transferred above the susceptor by a transfer arm (not shown), and then descends to load the substrate to the susceptor. As another embodiment, the lift pin 1910 unloads the substrate by supporting and lifting the substrate above the susceptor, and then descends again when the substrate is transferred by the transfer arm.

The support 1920 or the supporting member is positioned in the inner space 1255 of the base plate 1250 and supports the lift pins 1910. The support 1920 may be connected to the driving unit 1930 or the lifting/lowering member.

The driving unit 1930 may be positioned outside the chamber 1100. A hydraulic or pneumatic cylinder may be used as the driving unit 1930, but is not limited thereto. Although one drive unit 1930 is illustrated in the drawing, a plurality of drive units may be provided to lift and lower each lift pin 1910

The support 1920 and the lift pin 1910 may be interconnected with the pin holder 1960.

The pin holder 1960 may include a top holder 1960a as a top body and a bottom holder 1960b as a bottom body. The top holder 1960a and the bottom holder 1960b may be threadedly coupled to each other. For example, a screw portion 1966 is provided in the top holder 1960a, and a screw hole 1967 to which the screw portion 1966 is fastened is provided in the bottom body 1960b.

The pin holder 1960 includes a ball socket 1962. A joint ball 1912 of the lift pin 1910 is inserted into the ball socket 1962 allowing pivoting of the lift pin 1910.

The lift pin 1910, e.g., the join ball 1912 within the ball socket 1962 may be operationally coupled to the ball socket 1962 via a first elastomer 1970. The first elastomer 1970 may provide a restoring force to restore the lift pin 1910 to an original coaxial position (central axis C) with the pin holder 1960 from a non-coaxial position with the pin holder 1970 caused by pivoting of the joint ball 1912. The first elastomer 1970 may be elastically modified by the pivoting of the joint ball 1912, but may restore to its original state, thereby maintaining the lift pin in its original position. In an embodiment, the first elastomer 1970 may be provided in a pin shape and be made of a silicon material having an elastic restoring force. One end of the first elastomer 1970 is inserted into a first insertion groove 1914 of the joint ball 1912, and the other opposite end is inserted into a second insertion groove 1964 of the ball socket 1962. The first insertion groove 1914 and the second insertion groove 1964 are vertically aligned with the central axis C being their central axis.

The pin holder 1960 may be provided to the support 1920 to be movable laterally, e.g., in the horizontal direction. The pin holder 1960 may be connected to the support 1920 via a second elastomer 1980, allowing lateral movement of the pin holder 1960 with respect to the support 1920.

The second elastomer 1980 may provide a restoring force to restore the pin holder 1960 an original position with respect to the support 1920 from laterally moved position. The second elastomer 1980 may be elastically modified by lateral movement of the pin holder 1960, but may restore to its original state, thereby maintaining the pin holder 1960 in its original position with respect to the support 1920 The second elastic modification member 1980 may be provided in a pin shape and be made of a silicon material having an elastic restoring force. One end of the second elastomer 1980 is inserted into a third insertion groove 1968 formed on a bottom of the pin holder 1960, and the other opposite end is inserted into a fourth insertion groove 1922 formed on the top of the support unit 1920. The third insertion groove 1968 and the fourth insertion groove 1922 are aligned vertically, with the central axis C being their central axis.

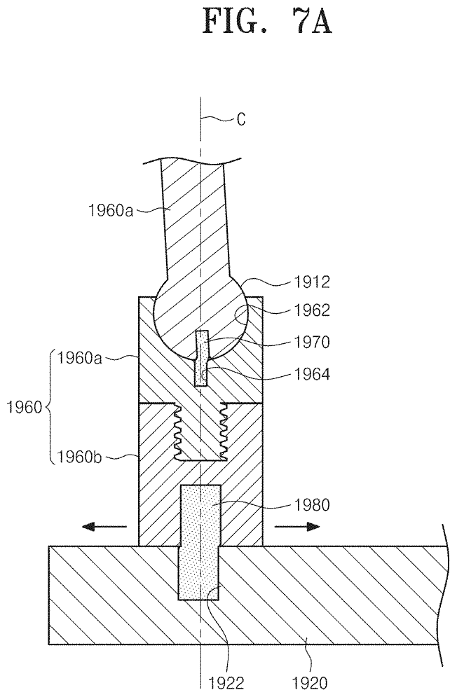

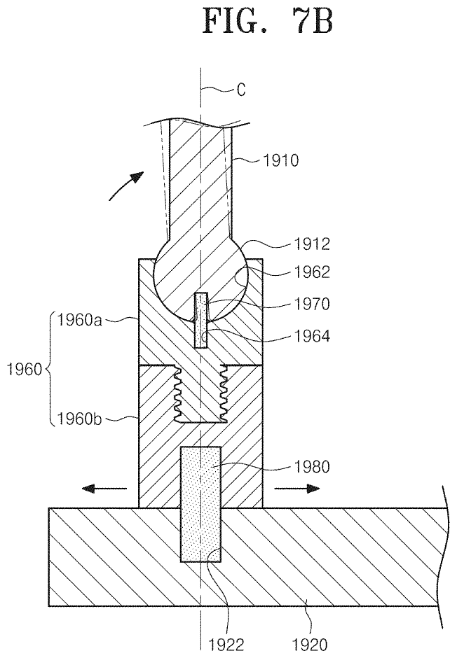

FIG. 7A and FIG. 7B illustrate that the lift pin returns to its original position (e.g., coaxial with the central axis C) by the first and second elastomers.

As shown in FIG. 7A and FIG. 7B, if the susceptor of the substrate support unit 1200 is in an extremely low temperature state by the refrigerant, the susceptor may shrink. In this case, since the joint ball 1912 may pivot within the ball socket and the pin holder 1960 may laterally move, a stress between the lift pin 1910 and the pin holder 1960 may be minimized to prevent a damage. At this time, the first elastomer 1970 may be elastically deformed by pivoting of the joint ball 1912, and the second elastomer 1980 may be elastically deformed by a lateral movement of the pin holder 1960.

As shown in FIG. 7B, if a thermal deformation of the susceptor is removed, the first and second elastomers 1970 and 1980 return to its original shape or state, thereby returning the lift pin 1910 and the pin holder 1960 return to their original state, aligning their axis with the central axis C.

The substrate support unit according to the inventive concept may be applied to not only the inductively coupled plasma (ICP) apparatus shown in the embodiment but also other plasma treating apparatuses. Other plasma treating apparatuses include a capacitive coupled plasma (CCP), a plasma treating apparatus using a radial line slot antenna, a Helicon Wave Plasma (HWP) apparatus, and an electron cyclotron resonance plasma (ECR) apparatus.

In addition, the substrate treated by the substrate treating apparatus according to the inventive concept is not limited to wafers, and may be, for example, a large substrate for a flat panel display, an EL element, or a substrate for a solar cell.

Although the etching process has been described as an embodiment, it may also be applied to a substrate treating apparatus which performs a deposition process.

Since not all of its components or configuration steps are essential in the embodiments described in the specification, the inventive concept may selectively include part of its components or configuration steps. In addition, since the configuration steps do not necessarily have to be performed in the order described, it is also possible that the steps described later are performed prior to the steps described first.

Furthermore, the above-described embodiments may not necessarily be performed independently, but may be used individually or in combination with each other.

What is claimed is:

1. A substrate support unit for supporting a substrate comprising:
a susceptor supporting the substrate and having a pinhole formed vertically; and
a lift pin unit configured to load and unload the substrate on the susceptor, and
wherein the lift pin unit comprises:
a lift pin vertically movable along the pinhole;
a support vertically movable by a driving unit;
a pin holder connecting the support and the lift pin, and
wherein the lift pin is pivotably connected to the pin holder and
the pin holder is laterally movable with respect to the support.

2. The substrate support unit of claim 1, wherein the lift pin includes a joint ball, and
the pin holder includes a ball socket into which the joint ball is inserted for pivoting of the join ball.

3. The substrate support unit of claim 2, wherein the lift pin unit further comprises a first elastomer for providing a restoring force to restore the lift pin to an original coaxial position with the pin holder from a non-coaxial position with the pin holder caused by pivoting of the joint ball.

4. The substrate support unit of claim 3, wherein the first elastomer comprises a pin-shaped elastomer having one end inserted into a first insertion groove of the join ball and the other opposite end of the first elastomer inserted into a second insertion groove of the ball socket.

5. The substrate support unit of claim 4, wherein the first insertion groove and the second insertion groove are vertically aligned.

6. The substrate support unit of claim 2, wherein the lift pin unit further comprises a second elastomer for proving a restoring force to restore the pin holder to an original position with respect to the support from laterally moved position.

7. The substrate support unit of claim 6, wherein the second elastomer comprises a pin-shaped elastomer having one end inserted into a third insertion groove formed at a bottom of the pin holder and the other opposite end of the second elastomer inserted into a fourth insertion groove formed a top of the support.

8. The substrate support unit of claim 7, wherein the third insertion groove and the fourth insertion groove are vertically aligned.

9. A lift pin unit for loading and unloading a substrate comprising:
a lift pin;
a support vertically movable by a driving unit; and
a pin holder connecting the support and the lift pin, and
wherein the lift pin is pivotably connected to the pin holder, and
wherein the lift pin includes a joint ball, and
the pin holder includes a ball socket into which the joint ball is inserted for pivoting of the joint ball.

10. The lift pin unit of claim 9 further comprising a first elastomer for providing a restoring force to restore the lift pin to an original coaxial position with the pin holder from a non-coaxial position with the pin holder caused by pivoting of the joint ball.

11. The lift pin unit of claim 10, wherein the first elastomer comprises a pin-shaped elastomer having one end inserted into a first insertion groove of the joint ball and the other opposite end inserted into a second insertion groove of the ball socket.

12. The lift pin unit of claim 11, wherein the first insertion groove and the second insertion groove are vertically aligned.

13. The lift pin unit of claim 9, wherein the pin holder is laterally movably connected to the support, and
wherein the lift pin unit further comprises a second elastomer for providing a restoring force to restore the pin holder to an original position with the support from laterally moved position.

14. The lift pin unit of claim 13, wherein the second elastomer comprises a pin-shaped elastomer having one end inserted into a third insertion groove formed at bottom of the pin holder and the other opposite end inserted into a fourth insertion groove formed a top the support.

15. The lift pin unit of claim 14, wherein the third insertion groove and the fourth insertion groove are vertically aligned.

16. The lift pin unit of claim 9, wherein the pin holder includes a top holder connected to the lift pin and a bottom holder connected to the support, and
wherein the top holder and the bottom holder are threadedly connected.

17. A substrate treating apparatus comprising:
a process chamber defining a treating space;
a gas supply unit configured to supply a process gas into the process chamber;
a plasma generation unit configured to generate a plasma from the process gas introduced into the process chamber; and
a substrate support unit provided at the treating space and configured to support a substrate, and
wherein the substrate support unit comprises:
a dielectric plate having an electrostatic electrode therein electrostatically adsorbing the substrate;
an electrode plate provided below the dielectric plate and having a fluid channel;
a focus ring in a ring shape provided at a periphery of the dielectric plate;
an insulator plate provided below the electrode plate;
a base plate provided below the insulator plate and grounded; and
a lift pin unit provided in an inner space of the base plate, and
wherein lift pin unit includes:
a lift pin inserted into a pin hole penetrating the dielectric plate, the electrode plate, and the insulator plate;
a support vertically movable by a driving unit; and
a pin holder connecting the support unit and the lift pin, and
wherein the lift pin is pivotably connected to the pin holder pivotable on a central axis of the pinhole, and
the pin holder is vertically movably connected to the support unit.

18. The substrate treating apparatus of claim 17, wherein the lift pin includes a joint ball, and
the pin holder includes a ball socket into which the joint ball is inserted for pivoting of the joint ball, and
the lift pin unit further includes a first elastomer for providing a restoring force to restore the lift pin to an original position coaxial with the central axis of the pin hole from a pivotally moved position.

19. The substrate treating apparatus of claim 18, wherein the lift pin unit further includes a second elastomer for providing a restoring force to restore the pin holder to an original position coaxial with the central axis of the pin hole from a laterally moved position, and
wherein the second elastomer comprises a pin-shaped elastomer having one end inserted into an insertion groove formed at a bottom of the pin holder and the other opposite end inserted into an insertion grooved formed a top of the support.

20. The substrate treating apparatus of claim 17, wherein the process chamber treats the substrate using a cryogenic plasma.
